(19) United States
(12) Patent Application Publication
(10) Pub. No.: US 2024/0357875 A1
(43) Pub. Date: Oct. 24, 2024

(54) DISPLAY PANEL

(71) Applicant: Samsung Display Co., LTD., Yongin-si (KR)

(72) Inventors: SOYUL JEON, Yongin-si (KR); YEONJU SEO, Yongin-si (KR)

(21) Appl. No.: 18/431,398

(22) Filed: Feb. 2, 2024

(30) Foreign Application Priority Data
Apr. 18, 2023 (KR) 10-2023-0050503

(51) Int. Cl. H10K 59/123; G09G 3/32; H10K 59/80

(52) U.S. Cl. CPC H10K 59/123; G09G 3/32; H10K 59/873; G09G 2300/0819; G09G 2300/0842

(57) ABSTRACT

A display panel includes a base layer, a transistor including a semiconductor pattern disposed on the base layer and a control electrode which overlaps the semiconductor pattern, a first connecting electrode connected to the semiconductor pattern, a second connecting electrode connected to the first connecting electrode, a light emitting element including a first electrode connected to the second connecting electrode, a second electrode, and an emission pattern disposed between the first electrode and the second electrode, an encapsulation layer covering the light emitting element, a first pattern disposed in a same layer as the first connecting electrode, and a second pattern which is disposed in a same layer as the second connecting electrode and covers an end of the first pattern disposed away from the display region. The end of the first pattern includes an inclined portion inclined at a predetermined angle.

This application claims priority to Korean Patent Application No. 10-2023-0050503, filed on Apr. 18, 2023, and all the benefits accruing therefrom under 35 U.S.C. § 119, the content of which in its entirety is herein incorporated by reference.

### BACKGROUND

### 1. Field

Embodiments of the disclosure described herein relate to a display device, and more particularly, relate to a display panel having improved quality.

### 2. Description of the Related Art

A display device is activated depending on an electrical signal. The display device may be constituted by various layers such as a display panel that displays an image, an input sensing layer that senses an external input, and the like. The various layers may be electrically connected together by signal lines arranged in various ways.

### SUMMARY

Embodiments of the disclosure provide a display panel in which a permeation path of moisture and oxygen is effectively blocked.

According to an embodiment, the display panel includes a base layer, on which a display region and a peripheral region are defined, a transistor including disposed on the base layer, where the transistor includes a semiconductor pattern overlapping the display region and disposed on the base layer and a control electrode overlapping the semiconductor pattern, a first connecting electrode disposed on the semiconductor pattern and connected to the semiconductor pattern, a second connecting electrode disposed on the first connecting electrode and connected to the first connecting electrode, a light emitting element including a first electrode that overlapping the display region and connected to the second connecting electrode, a second electrode disposed over the first electrode, and an emission pattern disposed between the first electrode and the second electrode, an encapsulation layer covering the light emitting element, a first pattern disposed in a same layer as the first connecting electrode, and a second pattern that is disposed in a same layer as the second connecting electrode, wherein the second pattern overlaps the peripheral region and covers an end of the first pattern disposed away from the display region. In such an embodiment, the end of the first pattern includes an inclined portion inclined at a predetermined angle.

In an embodiment, in the peripheral region, the second electrode may contact with the first electrode, and in the peripheral region, the first electrode may contact with the second pattern.

In an embodiment, the light emitting element may receive a power voltage through the first pattern and the second pattern.

In an embodiment, the first connecting electrode and the first pattern may include a same material as each other, and the second connecting electrode and the second pattern may include a same material as each other.

In an embodiment, the first pattern may include a first conductive layer, a second conductive layer, and a third conductive layer sequentially stacked one on another. In such an embodiment, the first conductive layer and the third conductive layer may include a same material as each other, and the inclined portion may be defined by the second conductive layer.

In an embodiment, an end of the first conductive layer may be farther away from the display region than an end of the third conductive layer is.

In an embodiment, an end of the first conductive layer may further protrude in a direction away from the display region than an end of a lower surface of the second conductive layer does, and an end of the third conductive layer may further protrude in the direction away from the display region than an end of an upper surface of the second conductive layer does.

In an embodiment, an end of the first conductive layer may further protrude in a direction away from the display region than an end of a lower surface of the second conductive layer does, and an end of an upper surface of the second conductive layer may further protrude in the direction away from the display region than an end of the third conductive layer does, and a portion of the upper surface of the second conductive layer may be exposed from the third conductive layer.

In an embodiment, on a cross-section, the inclined portion may be concave toward the base layer.

In an embodiment, on a cross-section, the inclined portion may have an uneven surface.

In an embodiment, the first conductive layer and the third conductive layer may include titanium, and the second conductive layer may include aluminum. In such an embodiment, the second conductive layer may have a thickness greater than a thickness of the first conductive layer and a thickness of the third conductive layer.

In an embodiment, the encapsulation layer may include a first inorganic layer covering the light emitting element, a second inorganic layer disposed over the first inorganic layer, and an organic layer disposed between the first inorganic layer and the second inorganic layer. In such an embodiment, the first inorganic layer and the second inorganic layer may contact with each other in the peripheral region and may cover the second pattern.

In an embodiment, the first inorganic layer and the second inorganic layer may contact with each other in a region overlapping the inclined portion.

In an embodiment, the display panel may further include a buffer layer disposed on the base layer, where the buffer layer is disposed between the base layer and the semiconductor pattern, a first insulating layer disposed on the buffer layer, where the third insulating layer is disposed between the second insulating layer and the control electrode, a second insulating layer disposed on the first insulating layer, a third insulating layer disposed on the second insulating layer, where the third insulating layer is disposed between the second insulating layer and the first connecting electrode, a fourth insulating layer disposed on the third insulating layer, where the fourth insulating layer is disposed between the third insulating layer and the second connecting electrode, a fifth insulating layer disposed on the fourth insulating layer, where the fifth insulating layer is disposed between the fourth insulating layer and the first electrode, a pixel defining layer disposed on the fifth insulating layer, where the pixel defining layer is provided with an opening defined therein to expose at least a portion of the first electrode, a first dam part overlapping the peripheral region, where the first dam part includes a same material as at least one selected from the first to fifth insulating layers, and a second dam part disposed farther away from the display region than the first dam part is, where the second dam part includes a same material as at least one selected from the first to fifth insulating layers.

In an embodiment, the end of the first pattern may be disposed between the first dam part and the second dam part.

In an embodiment, a boundary of the organic layer may be defined by one of the first dam part and the second dam part.

In an embodiment, the display panel may further include a third dam part disposed on the first insulating layer overlapping the peripheral region. In such an embodiment, the third dam part may be disposed farther away from the display region than the second dam part is, and the third dam part may include a same material as at least one selected from the first to fifth insulating layers.

In an embodiment, the first connecting electrode may be connected to the semiconductor pattern through a first contact hole defined in the first insulating layer, the second insulating layer, and the third insulating layer, the second connecting electrode may be connected to the first connecting electrode through a second contact hole defined in the fourth insulating layer, and the first electrode may be connected to the second connecting electrode through a third contact hole defined in the fifth insulating layer.

In an embodiment, the display region may include long sides and short sides which cross each other. In such an embodiment, points where the long sides and the short sides meet may be defined as corners, and the first pattern and the second pattern may contact with each other in corner areas of the peripheral region adjacent to the corners.

In an embodiment, the inclined portion may have a width in a range of about 6 micrometers (μm) to about 15 μm.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of a display device according to an embodiment of the disclosure.

FIG. 2 is a cross-sectional view of the display device according to an embodiment of the disclosure.

FIG. 3A is a block diagram of a display panel according to an embodiment of the disclosure.

FIG. 3B is an equivalent circuit diagram of a pixel according to an embodiment of the disclosure.

FIGS. 4A and 4B are plan views of the display panel according to embodiments of the disclosure.

FIG. 5 is a cross-sectional view taken along line I-I′ of FIG. 1.

FIG. 6A is a cross-sectional view taken along line II-II′ of FIG. 1.

FIG. 6B is an enlarged cross-sectional view of portion AA′ of FIG. 6A.

FIG. 7 is a cross-sectional view illustrating a comparative example.

FIG. 8A is a cross-sectional view of a partial region of the display panel according to an embodiment of the disclosure.

FIG. 8B is a cross-sectional view of a partial region of the display panel according to an embodiment of the disclosure.

FIGS. 9A to 9J are cross-sectional views illustrating a display panel manufacturing method according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component.

In addition, terms such as “below”, “under”, “above”, and “over” are used to describe a relationship of components illustrated in the drawings. The terms are relative concepts and are described based on directions illustrated in the drawing.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

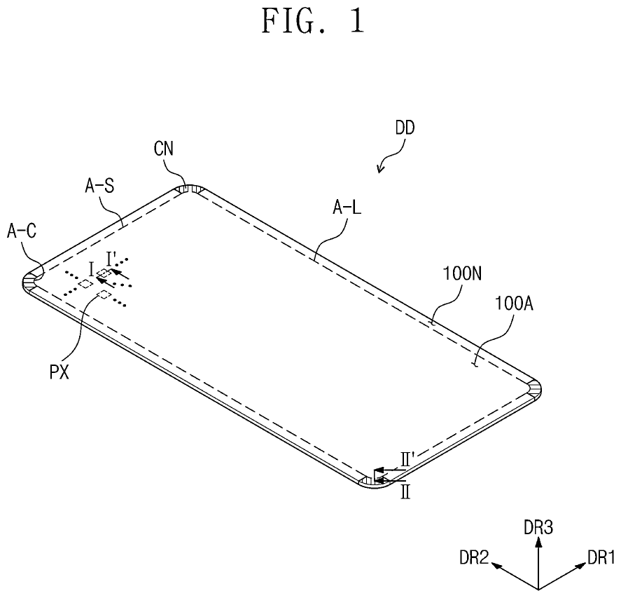

FIG. 1 is a perspective view of a display device according to an embodiment of the disclosure.

Referring to FIG. 1, the display device DD according to an embodiment may generate an image and may sense an external input. The display device DD may include a display region 100A and a peripheral region 100N. Pixels PX are disposed in the display region 100A. The pixels PX may include first color pixels (hereinafter, referred to as the first pixels), second color pixels (hereinafter, referred to as the second pixels), and third color pixels (hereinafter, referred to as the third pixels) that generate light having different colors.

The display region 100A may display an image. The display region 100A may include a plane defined by a first direction DR1 and a second direction DR2. However, the shape of the display region 100A is not limited thereto. Here, a third direction DR3 may be a direction perpendicular to the first direction DR1 and the second direction DR2, and may be a thickness direction of the display device DD.

The display region 100A according to an embodiment may include short sides A-S that extend in the first direction DR1 and that are spaced apart from each other in the second direction DR2 and long sides A-L that extend in the second direction DR2 and that are spaced apart from each other in the first direction DR1. Portions where the short sides A-S and the long sides A-L meet may be defined as corners A-C. In an embodiment, as shown in FIG. 1, the corners A-C may have a rounded shape. Alternatively, without being limited thereto, the corners A-C may have an angled shape.

The display device DD according to an embodiment of the disclosure may block a movement path of moisture and oxygen that permeate from corner areas CN of the peripheral region 100N that are adjacent to the corners A-C. Such features will be described later in detail.

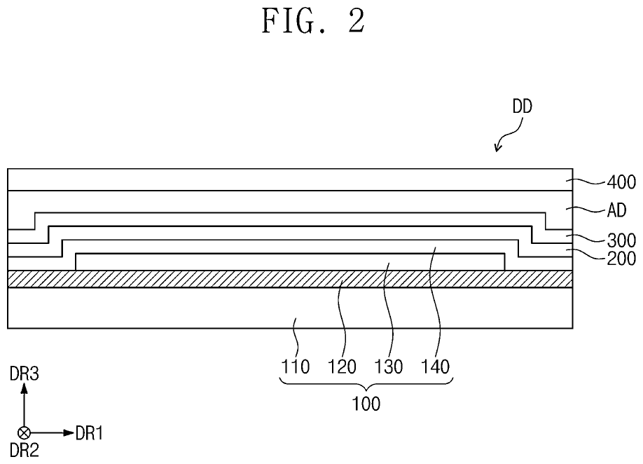

FIG. 2 is a cross-sectional view of the display device according to an embodiment of the disclosure.

Referring to FIG. 2, the display device DD may include a display panel 100, an input sensor 200, an anti-reflector 300, and a window 400.

The display panel 100 may be an emissive display panel. In an embodiment, for example, the display panel 100 may be an organic light emitting display panel, an inorganic light emitting display panel, a micro-light emitting diode (LED) display panel, or a nano-LED display panel. The display panel 100 may include a base layer 110, a driving element layer 120, a light emitting element layer 130, and an encapsulation layer 140.

The base layer 110 may provide a base surface on which the driving element layer 120 is disposed. The base layer 110 may be a rigid substrate, or a flexible substrate that can be bent, folded, or rolled. The base layer 110 may be a glass substrate, a metal substrate, or a polymer substrate. However, embodiments of the disclosure are not limited thereto, and alternatively, the base layer 110 may include an inorganic layer, an organic layer, or a composite layer.

The base layer 110 may have a multi-layer structure. In an embodiment, for example, the base layer 110 may include a first synthetic resin layer, an inorganic layer having a multi-layer structure or a single-layer structure, and a second synthetic resin layer disposed on the inorganic layer having the multi-layer structure or the single-layer structure. In such an embodiment, each of the first and second synthetic resin layers may include a polyimide-based resin, but is not particularly limited.

The driving element layer 120 may be disposed on the base layer 110. The driving element layer 120 may include an insulating layer, a semiconductor pattern, and a conductive pattern. The driving element layer 120 includes drive circuits of the pixels PX described with reference to FIG. 1.

The light emitting element layer 130 may be disposed on the driving element layer 120. The light emitting element layer 130 may include light emitting elements LD of the pixels PX described with reference to FIG. 1. I nan embodiment, for example, the light emitting elements LD may include an organic light emitting material, an inorganic light emitting material, an organic-inorganic light emitting material, a quantum dot, a quantum rod, a micro-LED, or a nano-LED.

The encapsulation layer 140 may be disposed on the light emitting element layer 130. The encapsulation layer 140 overlaps emissive regions LA-R, LA-G, and LA-B and a non-emissive region NLA and covers the light emitting elements LD. The encapsulation layer 140 may protect the light emitting element layer 130 from foreign matter such as moisture, oxygen, and dust particles. The encapsulation layer 140 may include at least one inorganic layer. The encapsulation layer 140 may include a stacked structure of an inorganic layer/an organic layer/an inorganic layer.

The input sensor 200 may be disposed on the display panel 100. The input sensor 200 may sense an external input applied from the outside. The external input may be an input of a user. The input of the user may include various types of external inputs, such as a part of the user's body, light, heat, a pen, or pressure.

In an embodiment, the input sensor 200 may be formed on the display panel 100 through a continuous process. In such an embodiment, the input sensor 200 may be directly disposed on the display panel 100. The expression “component B is directly disposed on component A” used herein may mean that a third component is not disposed between component A and component B. In such an embodiment, for example, an adhesive layer may not be disposed between the input sensor 200 and the display panel 100.

The anti-reflector 300 may be disposed on the input sensor 200. The anti-reflector 300 may decrease the reflectance of external light. In an embodiment, the anti-reflector 300 may be directly formed on the input sensor 200 through a continuous process.

The anti-reflector 300 may include a light blocking pattern overlapping a reflection structure disposed on a lower side of the anti-reflector 300. The anti-reflector 300 may further include color filters overlapping the emissive regions that will be described below. The color filters may include first color filters, second color filters, and third color filters that correspond to the first pixels, the second pixels, and the third pixels. The color filters decrease the reflectance of external light by absorbing light in a predetermined wavelength range of the external light. Features of the anti-reflector 300 will be described later in detail.

The window 400 may be disposed on the anti-reflector 300. The window 400 and the anti-reflector 300 may be coupled by an adhesive layer AD. In an embodiment, for example, the adhesive layer AD may be a pressure sensitive adhesive (PSA) film or an optically clear adhesive (OCA) film.

The window 400 includes at least one base layer. The base layer may be a glass substrate or a synthetic resin film. The window 400 may have a multi-layer structure. The window 400 may include a thin glass substrate and a synthetic resin film disposed on the thin glass substrate. The thin glass substrate and the synthetic resin film may be coupled by an adhesive layer. The adhesive layer and the synthetic resin film may be separated or separable from the thin glass substrate for replacement of the adhesive layer and the synthetic resin film.

The window 400 may further include functional layers disposed on the base layer. The window 400 may further include a hard coating layer, an anti-scattering layer, an anti-fingerprint layer, and the like.

In an embodiment of the disclosure, the adhesive layer AD may be omitted, and the window 400 may be directly disposed on the anti-reflector 300. The anti-reflector 300 may be coated with an organic material, an inorganic material, or a ceramic material.

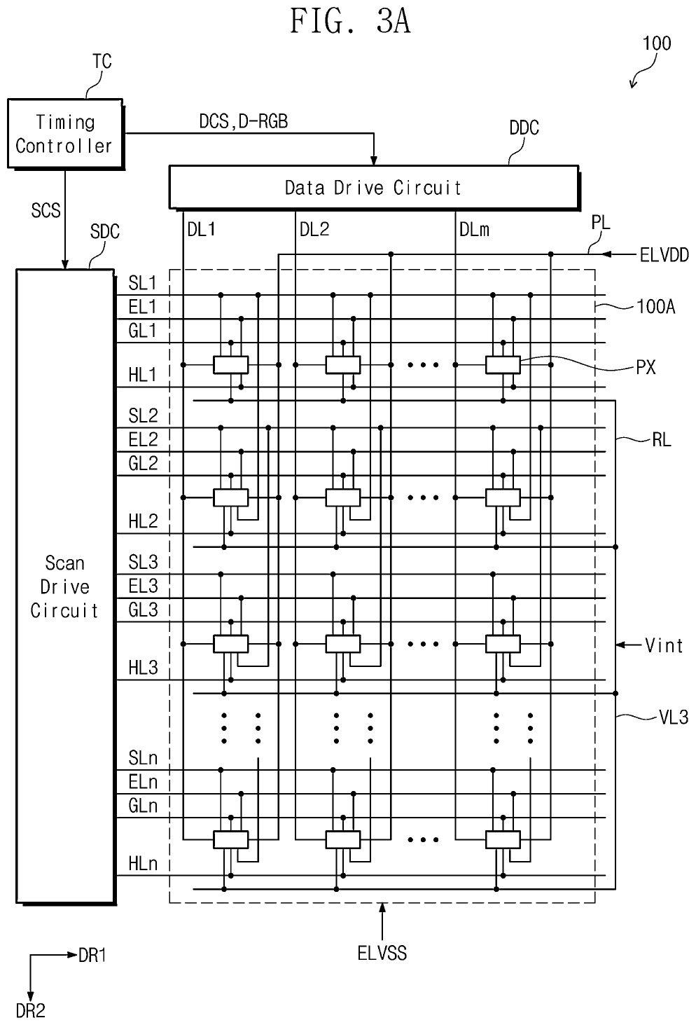

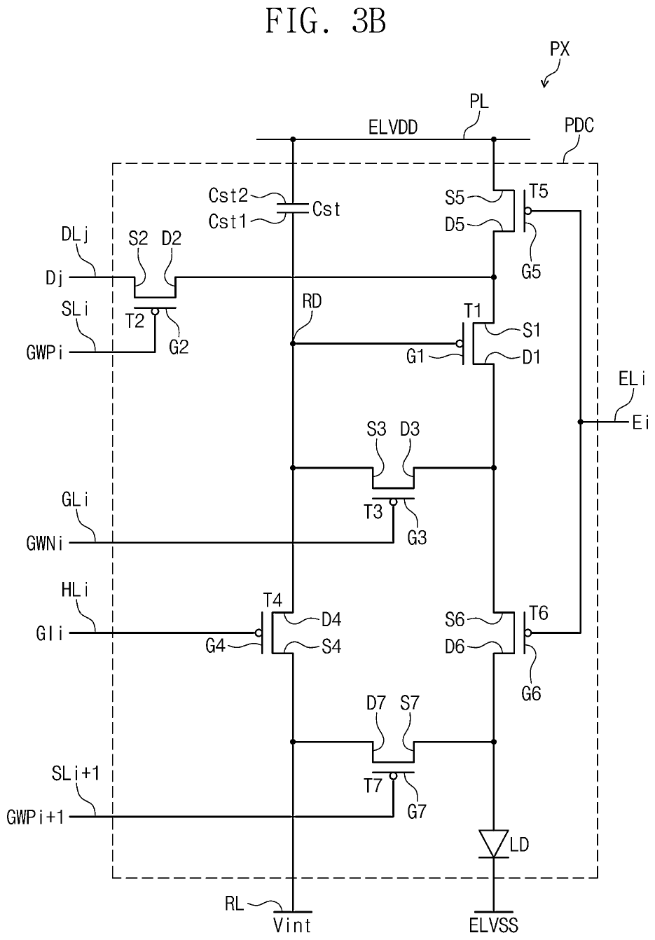

FIG. 3A is a block diagram of the display panel according to an embodiment of the disclosure. FIG. 3B is an equivalent circuit diagram of a pixel according to an embodiment of the disclosure.

Referring to FIG. 3A, an embodiment of the display panel 100 may include a timing controller TC, a scan drive circuit SDC, a data drive circuit DDC, and the pixels PX overlapping the display region 100A. In such an embodiment, the display panel 100 may be an organic light emitting display panel among emissive display panels, but not being limited thereto.

The timing controller TC receives input image signals and generates image data D-RGB by converting the data format of the input image signals according to the specification of an interface with the scan drive circuit SDC. The timing controller TC outputs the image data D-RGB and various control signals DCS and SCS.

The scan drive circuit SDC receives a scan control signal SCS from the timing controller TC. The scan control signal SCS may include a vertical start signal to start operation of the scan drive circuit SDC and a clock signal to determine the time to output signals. The scan drive circuit SDC generates a plurality of scan signals and sequentially outputs the scan signals to corresponding signal lines SL1 to SLn and GL1 to GLn. In addition, the scan drive circuit SDC generates a plurality of emission control signals in response to the scan control signal SCS and outputs the plurality of emission control signals to corresponding signal lines EL1 to ELn.

In FIG. 3A, an embodiment where the plurality of scan signals and the plurality of emission control signals are output from the one scan drive circuit SDC is illustrated as an example. However, the disclosure is not limited thereto. In an alternative embodiment of the disclosure, a plurality of scan drive circuits may separately generate and output scan signals and may separately generate and output a plurality of emission control signals. In addition, in an embodiment of the disclosure, a drive circuit that generates and outputs a plurality of scan signals and a drive circuit that generates and outputs a plurality of emission control signals may be separately distinguished from each other.

The data drive circuit DDC receives a data control signal DCS and the image data D-RGB from the timing controller TC. The data drive circuit DDC converts the image data D-RGB into data signals and outputs the data signals to a plurality of data lines DL1 to DLm that will be described below. The data signals are analog voltages corresponding to gray level values of the image data D-RGB.

The display panel 100 includes the first group of scan lines SL1 to SLn, the second group of scan lines GL1 to GLn, the third group of scan lines HL1 to HLn, the emission lines EL1 to ELn, the data lines DL1 to DLm, a first voltage line PL, a second voltage line RL, and the plurality of pixels PX. Here, each of n and m is a natural number. The first group of scan lines SL1 to SLn, the second group of scan lines GL1 to GLn, the third group of scan lines HL1 to HLn, and the emission lines EL1 to ELn extend in the first direction DR1 and are arranged in the second direction DR2 crossing the first direction DR1.

The plurality of data lines DL1 to DLm cross the first group of scan lines SL1 to SLn, the second group of scan lines GL1 to GLn, the third group of scan lines HL1 to HLn, and the emission lines EL1 to ELn to be insulated from the first group of scan lines SL1 to SLn, the second group of scan lines GL1 to GLn, the third group of scan lines HL1 to HLn, and the emission lines EL1 to ELn. Each of the plurality of pixels PX is connected to corresponding signal lines among the signal lines. A connection relationship between the pixels PX and the signal lines may be changed or variously modified depending on the configuration of the drive circuits of the pixels PX.

The first voltage line PL receives a first power voltage ELVDD. The second voltage line RL receives an initialization voltage Vint. The initialization voltage Vint has a lower level than the first power voltage ELVDD. A second power voltage ELVSS is applied to the light emitting elements LD (refer to FIG. 3B). The second power voltage ELVSS has a lower level than the first power voltage ELVDD.

The plurality of pixels PX may include a plurality of groups that generate light having different colors. In an embodiment, for example, the plurality of pixels PX may include red pixels that generate red light, green pixels that generate green light, and blue pixels that generate blue light. Light emitting elements of the red pixels, light emitting elements of the green pixels, and light emitting elements of the blue pixels may include emissive layers including or formed of different materials.

A pixel circuit PDC (refer to FIG. 3B) included in each of the pixels PX may include a plurality of transistors and a capacitor and a light emitting element LD (refer to FIG. 3B) that are electrically connected to the transistors. At least one of the scan drive circuit SDC or the data drive circuit DDC may include a plurality of transistors formed through a same process as the pixel circuit PDC (refer to FIG. 3B).

The above-described signal lines, the plurality of pixels PX, the scan drive circuit SDC, and the data drive circuit DDC may be formed on the base layer BL (refer to FIG. 2) through a plurality of photolithography processes. A plurality of insulating layers may be formed on the base layer 110 (refer to FIG. 2) through a plurality of deposition or coating processes. The plurality of insulating layers may be thin films disposed to correspond to the plurality of pixels PX, and some of the plurality of insulating layers may include an insulating pattern overlapping only a specific conductive pattern. The insulating layers include an organic layer and/or an inorganic layer.

A pixel PX connected to an i-th scan line SLi among the first group of scan lines SL1 to SLn and connected to a j-th data line DLj among the plurality of data lines DL1 to DLm is illustrated in FIG. 3B. Here, i is a natural number less than or equal to n, and j is a natural number less than or equal to m.

In an embodiment, as shown in FIG. 3B, the pixel circuit PDC may include first to seventh transistors T1 to T7, a capacitor Cst, and a light emitting element LD (refer to FIG. 3B). In such embodiment, the first transistor T1, the second transistor T2, and the fifth to seventh transistors T5 to T7 may be P-type transistors, and the third transistor T3 and the fourth transistor T4 may be N-type transistors.

Alternatively, without being limited thereto, the first to seventh transistors T1 to T7 may be implemented with one of a P-type transistor or an N-type transistor. In an embodiment of the disclosure, at least one selected from the first to seventh transistors T1 to T7 may be omitted.

In an embodiment, the first transistor T1 may be a drive transistor, and the second transistor T2 may be a switching transistor. The capacitor Cst is connected between the first voltage line PL, which receives the first power voltage ELVDD, and a reference node RN. The capacitor Cst includes a first electrode Cst1 connected to the reference node RD and a second electrode Cst2 connected to the first voltage line PL.

The first transistor T1 is connected between the first voltage line PL and one electrode of the light emitting element LD. A source S1 of the first transistor T1 is electrically connected to the first voltage line PL. Another transistor may or may not be disposed between the source S1 of the first transistor T1 and the first voltage line PL.

A drain D1 of the first transistor T1 is electrically connected to a first electrode AE of the light emitting element LD. Another transistor may or may not be disposed between the drain D1 of the first transistor T1 and the first electrode AE of the light emitting element LD. A gate G1 of the first transistor T1 is electrically connected to the reference node RD.

The second transistor T2 is connected between the j-th data line DLj and the source S1 of the first transistor T1. A source S2 of the second transistor T2 is electrically connected to the j-th data line DLj, and a drain D2 of the second transistor T2 is electrically connected to the source S1 of the first transistor T1. In an embodiment, a gate G2 of the second transistor T2 may be electrically connected to the i-th scan line SLi of the first group.

The third transistor T3 is connected between the reference node RD and the drain D1 of the first transistor T1. A drain D3 of the third transistor T3 is electrically connected to the drain D1 of the first transistor T1, and a source S3 of the third transistor T3 is electrically connected to the reference node RD. In such an embodiment, a gate G3 of the third transistor T3 may be electrically connected to an i-th scan line GLi of the second group.

The fourth transistor T4 is connected between the reference node RD and the second voltage line RL. A drain D4 of the fourth transistor T4 is electrically connected to the reference node RD, and a source S4 of the fourth transistor T4 is electrically connected to the second voltage line RL. In such an embodiment, a gate G4 of the fourth transistor T4 may be electrically connected to an i-th scan line HLi of the third group.

The fifth transistor T5 is connected between the first voltage line PL and the source S1 of the first transistor T1. A source S5 of the fifth transistor T5 is electrically connected to the first voltage line PL, and a drain D5 of the fifth transistor T5 is electrically connected to the source S1 of the first transistor T1. A gate G5 of the fifth transistor T5 may be electrically connected to an i-th emission line ELi.

The sixth transistor T6 is connected between the drain D1 of the first transistor T1 and the light emitting element LD. A source S6 of the sixth transistor T6 is electrically connected to the drain D1 of the first transistor T1, and a drain D6 of the sixth transistor T6 is electrically connected to the first electrode AE of the light emitting element LD. A gate G6 of the sixth transistor T6 may be electrically connected to the i-th emission line ELi.

The seventh transistor T7 is connected between the drain D6 of the sixth transistor T6 and the second voltage line RL. A source S7 of the seventh transistor T7 is electrically connected to the drain D6 of the sixth transistor T6, and a drain D7 of the seventh transistor T7 is electrically connected to the second voltage line RL. A gate G7 of the seventh transistor T7 may be electrically connected to an (i+1)-th scan line SLi+1 of the first group.

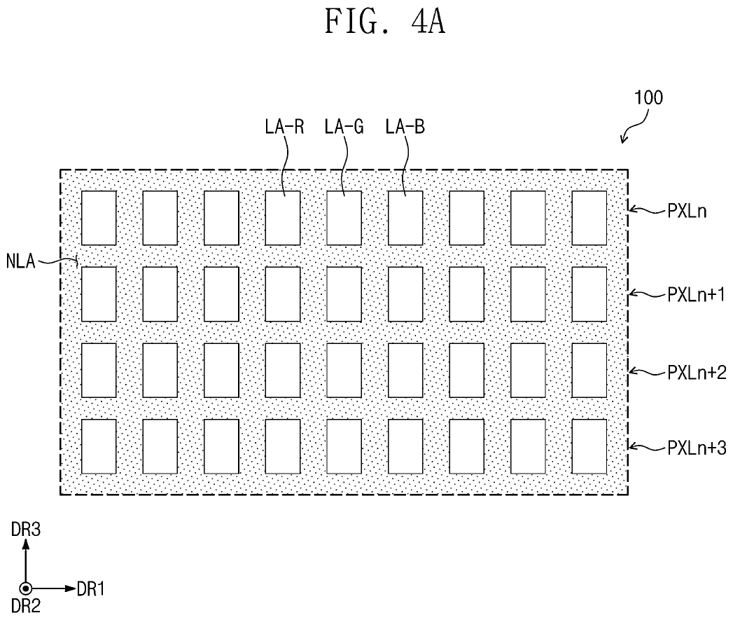

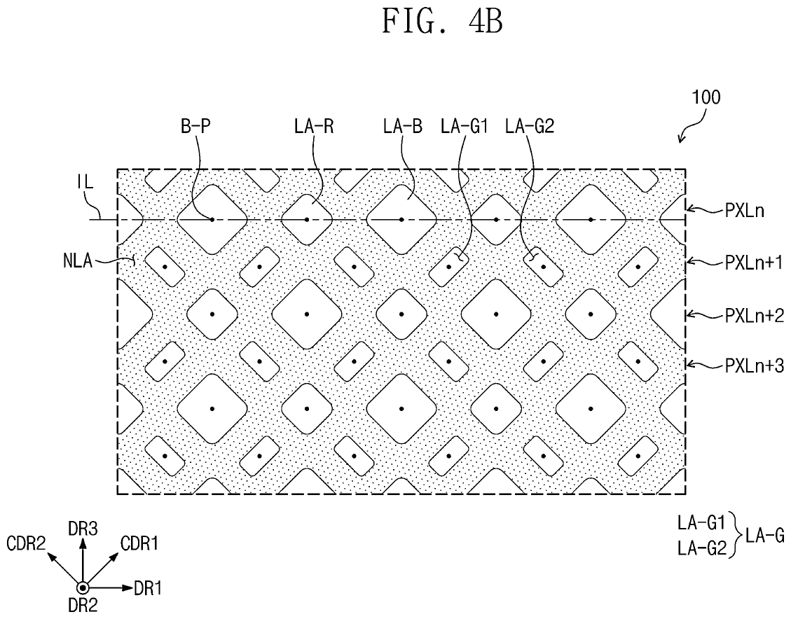

FIGS. 4A and 4B are plan views of the display panel according to embodiments of the disclosure.

A partial region of an embodiment of the display panel 100 that corresponds to the display region 100A of FIG. 1 is illustrated in FIG. 4A. The display panel 100 may include the first emissive regions LA-R, the second emissive regions LA-G, and the third emissive regions LA-B. The pixels PX described with reference to FIG. 1 may include the first to third pixels that generate light having different colors, respectively.

The light emitting elements LD (refer to FIG. 3B) of the first pixels are disposed in the first emissive regions LA-R, the light emitting elements LD (refer to FIG. 3B) of the second pixels are disposed in the second emissive regions LA-G, and the light emitting elements LD (refer to FIG. 3B) of the third pixels are disposed in the third emissive regions LA-B. In an embodiment, the first emissive regions LA-R may generate red light, the second emissive regions LA-G may generate green light, and the third emissive regions LA-B may generate blue light.

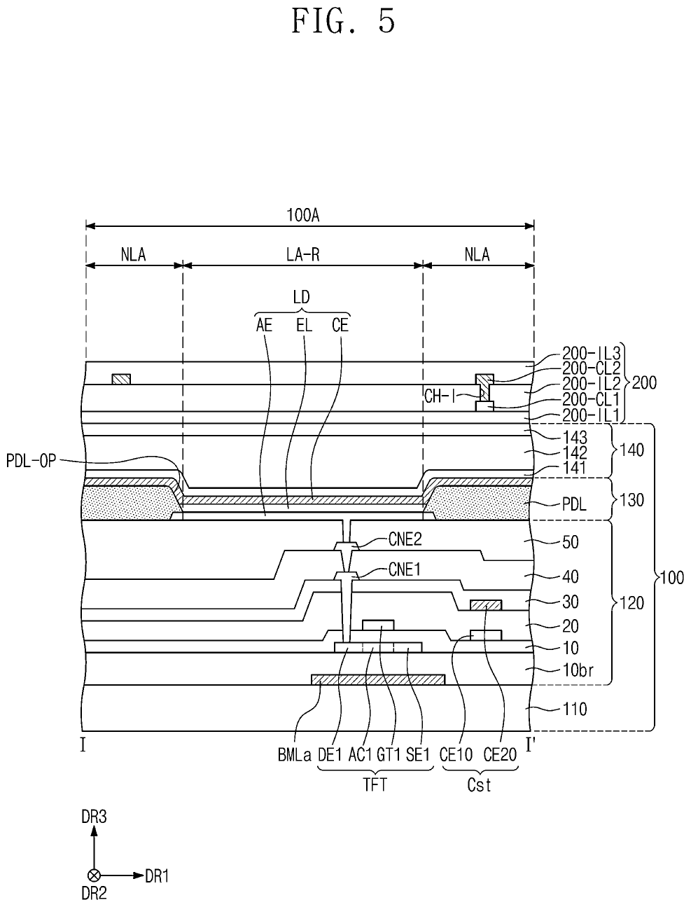

Although an embodiment where the first emissive regions LA-R, the second emissive regions LA-G, and the third emissive regions LA-B have a same planar area (or size) as each other is shown in FIG. 4A, the disclosure is not limited thereto. The emissive regions LA-R, LA-G, and LA-B may have the same shape as openings PDL-OP (refer to FIG. 5) formed in a pixel defining layer PDL (refer to FIG. 5). The non-emissive region NLA is disposed between the first emissive regions LA-R, the second emissive regions LA-G, and the third emissive regions LA-B.

A first emissive region LA-R, a second emissive region LA-G, and a third emissive region LA-B may define a unit emissive region, and unit emissive regions may be arranged in a matrix form. The arrangement of the first emissive regions LA-R, the second emissive regions LA-G, and the third emissive regions LA-B illustrated in FIG. 4A may be defined as a stripe arrangement.

The plurality of emissive regions LA-B, LA-R, and LA-G may define a plurality of pixel rows extending in the first direction DR1. The plurality of pixel rows may be arranged in the second direction DR2. The pixel rows may include an n-th pixel row PXLn (n is a natural number), an (n+1)-th pixel row PXLn+1, an (n+2)-th pixel row PXLn+2, and an (n+3)-th pixel row PXLn+3.

Referring to FIG. 4B, the first emissive regions LA-R, the second emissive regions LA-G, and the third emissive regions LA-B may have different planar areas (or sizes) for each other. Each of the first emissive regions LA-R, the second emissive regions LA-G, and the third emissive regions LA-B may have a “substantially polygonal shape”. The “substantially polygonal shape” includes a polygonal shape in a mathematical sense, a polygonal shape in which curves are defined at vertices, or a polygonal shape in which vertices include curves. The shapes of vertices may vary depending on an etching property of the pixel defining layer PDL illustrated in FIG. 5.

In an embodiment, the first emissive regions LA-R and the third emissive regions LA-B that have a quadrangular shape symmetrical with respect to the first direction DR1 and the second direction DR2 as illustrated in FIG. 4B. In such an embodiment, the second emissive regions LA-G having a quadrangular shape asymmetrical with respect to the first direction DR1 and the second direction DR2 as illustrated in FIG. 4B. The second emissive regions LA-G may be symmetrical with respect to a first oblique direction CDR1 crossing the first direction DR1 and the second direction DR2 and may be symmetrical with respect to a second oblique direction CDR2 perpendicular to the first oblique direction CDR1.

The second emissive regions LA-G may include second emissive regions LA-G1 of a first type (hereinafter, referred to as the first type emissive regions) and second emissive regions LA-G2 of a second type (hereinafter, referred to as the second type emissive regions) that are symmetrical with respect to the second direction DR2. In an embodiment of the disclosure, the second emissive regions LA-G may include only the first type emissive regions LA-G1 or may include only the second type emissive regions LA-G2. In an embodiment of the disclosure, the second emissive regions LA-G may be symmetrical with respect to the first direction DR1 and the second direction DR2.

In an embodiment of the disclosure, the first emissive regions LA-R and the third emissive regions LA-B may have a substantially square shape symmetrical with respect to the first direction DR1 and the second direction DR2. In an embodiment of the disclosure, the second emissive regions LA-G may have a substantially rectangular shape. The first type emissive regions LA-G1 and the second type emissive regions LA-G2 may have substantially rectangular shapes that are symmetrical with respect to the second direction DR2.

Referring to FIG. 4B, the n-th pixel row PXLn includes the first emissive regions LA-R and the third emissive regions LA-B alternately disposed in the first direction DR1. The (n+2-)th pixel row PXLn+2 includes the third emissive regions LA-B and the first emissive regions LA-R alternately disposed in the first direction DR1. The first emissive regions LA-R and the third emissive regions LA-B are arranged in the second direction DR2.

The arrangement order of the emissive regions in the n-th pixel row PXLn and the arrangement order of the emissive regions in the (n+2)-th pixel row PXLn+2 differ from each other. The third emissive regions LA-B and the first emissive regions LA-R in the n-th pixel row PXLn are staggered with respect to the third emissive regions LA-B and the first emissive regions LA-R in the (n+2)-th pixel row PXLn+2. The emissive regions in the n-th pixel row PXLn are shifted in the first direction DR1 by one emissive region with respect to the emissive regions in the (n+2)-th pixel row PXLn+2.

The second emissive regions LA-G are disposed in each of the (n+1)-th pixel row PXLn+1 and the (n+3)-th pixel row PXLn+3. The (n+1)-th pixel row PXLn+1 includes the second type emissive regions LA-G2 and the first type emissive regions LA-G1 alternately disposed in the first direction DR1. The (n+3)-th pixel row PXLn+3 includes the first type emissive regions LA-G1 and the second type emissive regions LA-G2 alternately disposed in the first direction DR1.

The emissive regions in the n-th pixel row PXLn are staggered with respect to the emissive regions in the (n+1)-th pixel row PXLn+1. The emissive regions in the (n+2)-th pixel row PXLn+2 are staggered with respect to the emissive regions in the (n+3)-th pixel row PXLn+3. The center points B-P of the emissive regions disposed in each of the four pixel rows PXLn, PXLn+1, PXLn+2, and PXLn+3 may be disposed on a same imaginary line IL.

As the plurality of emissive regions LA-R, LA-G, and LA-B define the above-described arrangement, four second emissive regions LA-G surround one first emissive region LA-R. Among the four second emissive regions LA-G, two second emissive regions LA-G face each other in the first oblique direction CDR1 with the one first emissive region LA-R therebetween, and the other two second emissive regions LA-G face each other in the second oblique direction CDR2 with the one first emissive region LA-R therebetween. In addition, four second emissive regions LA-G surround one third emissive region LA-B. Among the four second emissive regions LA-G, two second emissive regions LA-G face each other in the first oblique direction CDR1 with the one third emissive region LA-B therebetween, and the other two second emissive regions LA-G face each other in the second oblique direction CDR2 with the one third emissive region LA-B therebetween. The arrangement of the first emissive regions LA-R, the second emissive regions LA-G, and the third emissive regions LA-B illustrated in FIG. 4B may be defined as a diamond arrangement.

FIG. 5 is a cross-sectional view taken along line I-I′ of FIG. 1. In FIG. 5, for convenience of illustration and description, the anti-reflector 300 and the window 400 among the components of the display device DD described with reference to FIG. 2 are omitted.

Referring to FIG. 5, a cross-section that corresponds to the first emissive region LA-R and the non-emissive region NLA around the first emissive region LA-R is illustrated. In FIG. 5, a light emitting element LD included in a pixel PX and a transistor TFT connected to the light emitting element LD are illustrated. The transistor TFT may be one of a plurality of transistors included in a drive circuit of the pixel PX. In an embodiment, the transistor TFT may be a silicon transistor. Alternatively, the transistor TFT may be a metal oxide transistor.

A buffer layer 10br may be disposed on the base layer 110. The buffer layer 10br may prevent diffusion of metal atoms or impurities from the base layer 110 to a semiconductor pattern on an upper side of the buffer layer 10br. The semiconductor pattern includes an active region AC1 of the transistor TFT.

A rear metal layer BMLa may be disposed under the transistor TFT. The rear metal layer BMLa may prevent external light from reaching the transistor TFT. The rear metal layer BMLa may be disposed between the base layer 110 and the buffer layer 10br. In an embodiment of the disclosure, an inorganic barrier layer may be additionally disposed between the rear metal layer BMLa and the buffer layer 10br. The rear metal layer BMLa may be connected to an electrode or a line and may receive a constant voltage or a signal from the electrode or the line.

The semiconductor pattern may be disposed on the buffer layer 10br. In an embodiment, the semiconductor pattern may include a silicon semiconductor. In an embodiment, for example, the silicon semiconductor may include amorphous silicon or polycrystalline silicon. In an embodiment, for example, the semiconductor pattern may include low-temperature poly silicon.

The semiconductor pattern may include a first region having a high conductivity and a second region having a low conductivity. The first region may be doped with an N-type dopant or a P-type dopant. A P-type transistor may include a doped region that is doped with a P-type dopant, and an N-type transistor may include a doped region that is doped with an N-type dopant. The second region may be an un-doped region, or may be a region more lightly doped than the first region.

The first region may have a higher conductivity than the second region and may substantially serve as an electrode or a signal line. The second region may substantially correspond to the active region (or, the channel) of the transistor TFT. In other words, one portion of the semiconductor pattern may be the active region of the transistor TFT, another portion may be a source or drain of the transistor TFT, and another portion may be a connecting electrode or a connecting signal line.

A source region (or a source) SE1, the active region (or the channel) AC1, and a drain region (or a drain) DE1 of the transistor TFT may be formed from (or defined by portions of) the semiconductor pattern. The source region SE1 and the drain region DE1 may extend from the active region AC1 in opposite directions on the cross-section.

A first insulating layer 10 may be disposed on the buffer layer 10br. The first insulating layer 10 may commonly overlap the plurality of pixels PX (refer to FIG. 1) and may cover the semiconductor pattern. The first insulating layer 10 may include an inorganic layer and/or an organic layer and may have a single-layer structure or a multi-layer structure.

The inorganic layer may include at least one selected from aluminum oxide, titanium oxide, silicon oxide, silicon nitride, silicon oxy-nitride, zirconium oxide, and hafnium oxide. In an embodiment, the first insulating layer 10 may be a single silicon oxide layer. Not only the first insulating layer 10 but also insulating layers of the driving element layer 120 to be described below may be inorganic layers and/or organic layers and may have a single-layer structure or a multi-layer structure. The inorganic layers may include at least one selected from the aforementioned materials, but are not limited thereto.

A gate GT1 of the transistor TFT (also, referred to as “control electrode”) is disposed on the first insulating layer 10. The gate GT1 may be a portion of a metal pattern. The gate GT1 overlaps the active region AC1. The gate GT1 may function as a mask in a process of doping the semiconductor pattern. The gate GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), or indium zinc oxide (IZO), but is not particularly limited thereto.

A second insulating layer 20 may be disposed on the first insulating layer 10 and may cover the gate GT1. A third insulating layer 30 may be disposed on the second insulating layer 20. A second electrode CE20 of a storage capacitor Cst may be disposed between the second insulating layer 20 and the third insulating layer 30, and a first electrode CE10 of the storage capacitor Cst may be disposed between the first insulating layer 10 and the second insulating layer 20.

A first connecting electrode CNE1 may be disposed on the third insulating layer 30. The first connecting electrode CNE1 may be connected to the drain region DE1 of the transistor TFT through a contact hole defined in the first to third insulating layers 10, 20, and 30.

A fourth insulating layer 40 may be disposed on the third insulating layer 30. A second connecting electrode CNE2 may be disposed on the fourth insulating layer 40. The second connecting electrode CNE2 may be connected to the first connecting electrode CNE1 through a contact hole defined in the fourth insulating layer 40. A fifth insulating layer 50 may be disposed on the fourth insulating layer 40 and may cover the second connecting electrode CNE2. The stacked structure of the first to fifth insulating layers 10, 20, 30, 40, and 50 shown in FIG. 5 is merely illustrative, and an additional conductive layer and an additional insulating layer may be further disposed in addition to the first to fifth insulating layers 10, 20, 30, 40, and 50.

The fourth insulating layer 40 and the fifth insulating layer 50 may be organic layers. In an embodiment, for example, the organic layers may include a general purpose polymer, such as benzocyclobutene (BCB), polyimide, hexamethyldisiloxane (HMDSO), polymethylmethacrylate (PMMA) or polystyrene (PS), a polymer derivative having a phenolic group, an acrylate-based polymer, an imide-based polymer, an aryl ether-based polymer, an amide-based polymer, a fluorine-based polymer, a p-xylene-based polymer, a vinyl alcohol-based polymer, or a blend thereof.

The light emitting element LD may include a first electrode AE, a light emitting structure EL, and a second electrode CE. The first electrode AE may be disposed on the fifth insulating layer 50. The first electrode AE may be a (semi-) transmissive electrode or a reflective electrode. The first electrode AE may include a reflective layer formed of Ag, Mg, Al, Pt, Pd, Au, Ni, Nd, Ir, Cr, or a compound thereof and a transparent or translucent electrode layer disposed or formed on the reflective layer. The transparent or translucent electrode layer may include at least one selected from indium tin oxide (ITO), indium zinc oxide (IZO), indium gallium zinc oxide (IGZO), zinc oxide (ZnO), or indium oxide (In₂O₃) and aluminum-doped zinc oxide (AZO). In an embodiment, for example, the first electrode AE may have a stacked structure of ITO/Ag/ITO.

The pixel defining layer PDL may be disposed on the fifth insulating layer 50. According to an embodiment, the pixel defining layer PDL may have a property of absorbing light. In an embodiment, for example, the pixel defining layer PDL may be black in color. The pixel defining layer PDL may include a black coloring agent. The black coloring agent may include a black dye or a black pigment. The black coloring agent may include carbon black, metal such as chromium, or oxide thereof. The pixel defining layer PDL may correspond to a light blocking pattern having light blocking characteristics.

The pixel defining layer PDL may cover a portion of the first electrode AE. In an embodiment, for example, the pixel defining layer PDL may be provided with an opening PDL-OP defined therein to expose at least a portion of the first electrode AE. The opening PDL-OP of the pixel defining layer PDL may define the first emissive region LA-R.

The pixel defining layer PDL may increase the distance between the periphery of the first electrode AE and the second electrode CE. Accordingly, the pixel defining layer PDL may serve to prevent an arc from occurring at the periphery of the first electrode AE.

The light emitting structure EL includes at least an emission pattern. The light emitting structure EL may further include a hole control pattern disposed between the first electrode AE and the emission pattern. The hole control pattern may include a hole transport layer and may further include a hole injection layer. The light emitting structure EL may further include an electron control pattern disposed between the emission pattern and the second electrode CE. The electron control pattern may include an electron transport layer and may further include an electron injection layer.

The light emitting structure EL, that is, at least one selected from the emission pattern, the hole control pattern, or the electron control pattern, may be formed through an ink-jet process. The pattern formed through the ink-jet process is disposed in the opening PDL-OP. Accordingly, the second electrode CE may make contact with (contact or be in contact with) an upper surface of the pixel defining layer PDL.

The encapsulation layer 140 may be disposed on the light emitting element layer 130. The encapsulation layer 140 may include a first inorganic layer 141, an organic layer 142, and a second inorganic layer 143 sequentially stacked one above another. However, layers constituting the encapsulation layer 140 are not limited thereto. Each of the first inorganic layer 141, the organic layer 142, and the second inorganic layer 143 may have a single-layer structure or a multi-layer structure.

The first and second inorganic layers 141 and 143 may protect the light emitting element layer 130 from moisture and oxygen, and the organic layer 142 may protect the light emitting element layer 130 from foreign matter such as dust particles. The first and second inorganic layers 141 and 143 may include a silicon nitride layer, a silicon oxy-nitride layer, a silicon oxide layer, a titanium oxide layer, or an aluminum oxide layer. The organic layer 142 may include, but is not limited to, an acrylate-based organic layer.

The first and second inorganic layers 141 and 143 may be in contact with each other in the corner areas CN of the peripheral region 100N described with reference to FIG. 1 and may effectively block an inflow path of moisture and oxygen permeating into the corner areas CN from the outside.

The input sensor 200 may sense an external input applied from the outside. The external input may include various forms of inputs, such as a part of the user's body, light, heat, a pen, pressure, or the like.

In an embodiment, the input sensor 200 may be formed on the display panel 100 through a continuous process. In such an embodiment, the input sensor 200 may be directly disposed on the display panel 100. The expression “component B is directly disposed on component A” used herein may mean that a third component is not disposed between component A and component B. In such an embodiment, for example, an adhesive layer may not be disposed between the input sensor 200 and the display panel 100.

The input sensor 200 may include a first insulating layer 200-IL1, a first conductive pattern layer 200-CL1, a second insulating layer 200-IL2, a second conductive pattern layer 200-CL2, and a third insulating layer 200-IL3.

In an embodiment of the disclosure, the first insulating layer 200-IL1 and/or the third insulating layer 200-IL3 may be omitted. In such an embodiment where the first insulating layer 200-IL1 is omitted, the first conductive pattern layer 200-CL1 may be directly disposed on the uppermost insulating layer of the encapsulation layer 140. In an embodiment, the third insulating layer 200-IL3 may be replaced with an adhesive layer or an insulating layer of the anti-reflector 300 disposed on the input sensor 200. In an embodiment of the disclosure, the input sensor 200 may include only one of the first conductive pattern layer 200-CL1 and the second conductive pattern layer 200-CL2. In an embodiment of the disclosure, the input sensor 200 may be omitted.

The input sensor 200 includes first sensing electrodes and second sensing electrodes that cross each other. Bridge patterns may be disposed in regions where the first sensing electrodes and the second sensing electrodes cross each other. The bridge patterns may be formed from (or defined by portions of) the first conductive pattern layer 200-CL1 of FIG. 5. The remaining portions of the first sensing electrodes and the second electrodes other than the bridge patterns may be formed from (or defined by portions of) the second conductive pattern layer 200-CL2 of FIG. 5. The bridge patterns may be connected to corresponding conductive patterns of the second conductive pattern layer 200-CL2 through contact holes defined in the second insulating layer 200-IL2.

Conductive patterns of the first conductive pattern layer 200-CL1 and conductive patterns of the second conductive pattern layer 200-CL2 overlap the non-emissive region NLA. Openings corresponding to the emissive regions LA-R, LA-G, and LA-B of FIG. 4A may be defined in the first sensing electrodes and the second sensing electrodes. The openings of the first sensing electrodes and the second sensing electrodes may have a larger area than the openings PDL-OP of the pixel defining layer PDL.

The anti-reflector 300 may be disposed on the input sensor 200. The anti-reflector 300 may include a scattering pattern, a color filter, and an overcoat layer that overlap at least one selected from the emissive regions LA-R, LA-G, and LA-B described with reference to FIGS. 4A and 4B.

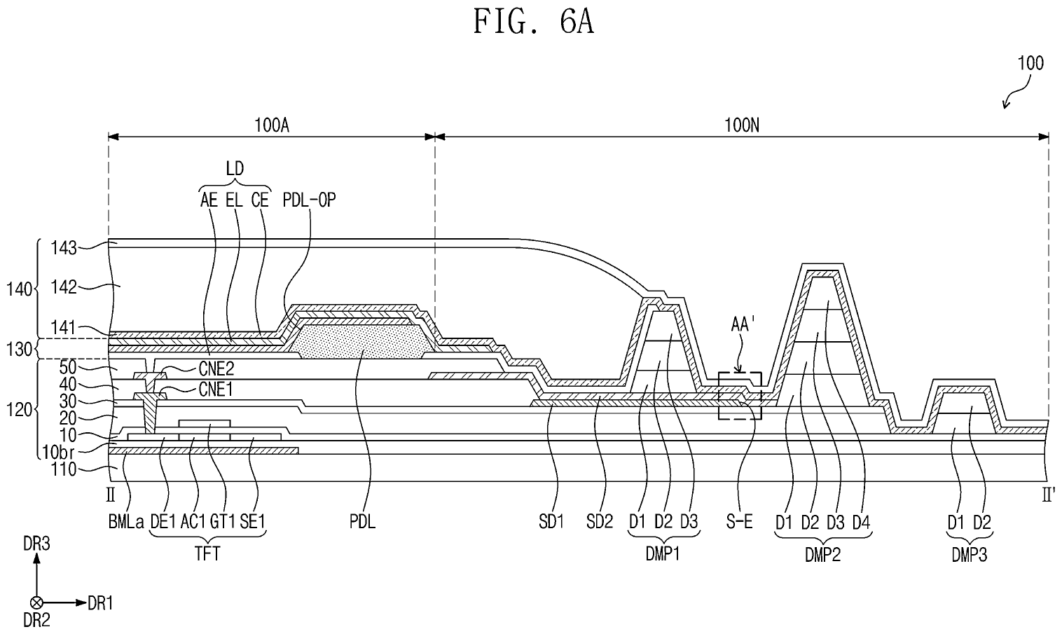

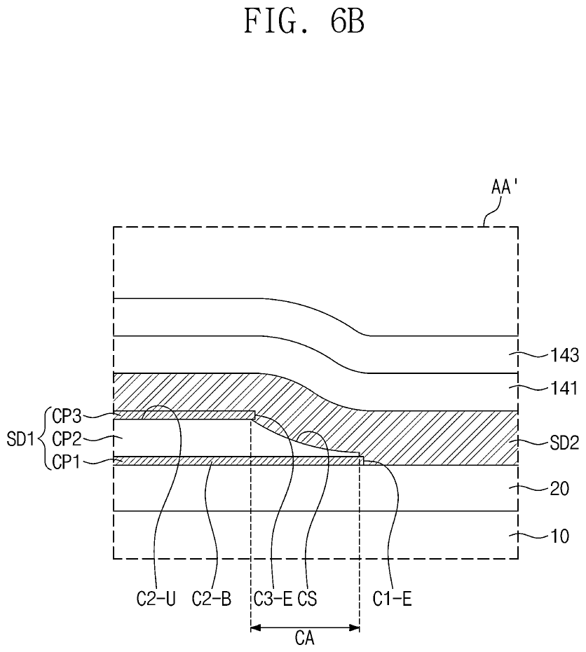

FIG. 6A is a cross-sectional view taken along line II-II′ of FIG. 1. FIG. 6B is an enlarged cross-sectional view of portion AA′ of FIG. 1. In FIG. 6A, for convenience of illustration and description, only a cross-sectional view of the display panel 100 among the components of the display device DD described with reference to FIG. 2 is illustrated. FIG. 6A illustrates a cross-sectional view of one of the corner areas CN described with reference to FIG. 1.

In an embodiment, the display panel 100 may include the base layer 110, the driving element layer 120, the light emitting element layer 130, and the encapsulation layer 140. The display region 100A of the display panel 100 may include the light emitting element LD and the transistor TFT that are included in the pixel PX (refer to FIG. 1). The components disposed in the display region 100A of the display panel 100 in FIG. 6A may correspond to those described above with reference to FIG. 5, and any repetitive detailed descriptions thereof will be omitted.

The display panel 100 according to an embodiment may include a first pattern SD1 and a second pattern SD2. Each of the first pattern SD1 and the second pattern SD2 may extend from the display region 100A to the peripheral region 100N. In an embodiment as shown in the cross-sectional view of FIG. 6A, the first pattern SD1 and the second pattern SD2 may be disposed only in the peripheral region 100N without being disposed in the display region 100A. However, the disclosure is not limited thereto. The first pattern SD1 and the second pattern SD2 may be in contact with each other in the peripheral region 100N.

According to an embodiment, an end S-E of the first pattern SD1 disposed away (or spaced apart) from the display region 100A may be covered by the second pattern SD2. The end S-E of the first pattern SD1 may be disposed between a first dam part DMP1 and a second dam part DMP2.

According to an embodiment, the first pattern SD1 may be disposed in (or directly on) a same layer as the first connecting electrode CNE1. Accordingly, the first pattern SD1 may be disposed on the third insulating layer 30 and may include a same material as the first connecting electrode CNE1. The second pattern SD2 may be disposed in (or directly on) a same layer as the second connecting electrode CNE2. Accordingly, the second pattern SD2 may be disposed on the fourth insulating layer 40 and may include a same material as the second connecting electrode CNE2.

The display panel 100 according to an embodiment may include the first to third dam parts DMP1, DMP2, and DMP3. The first dam part DMP1 may be disposed closest to the display region 100A, and the third dam part DMP3 may be disposed furthest from the display region 100A. The second dam part DMP2 may be disposed between the first dam part DMP1 and the third dam part DMP3.

The first dam part DMP1 may be disposed on the second pattern SD2. The second dam part DMP2 may be disposed on the third insulating layer 30. The third dam part DMP3 may be disposed on the first insulating layer 10.

Each of the first to third dam parts DMP1, DMP2, and DMP3 may include multiple layers including a same material as at least one selected from the first to fifth insulating layers 10, 20, 30, 40, and 50 described with reference to FIG. 5.

The first dam part DMP1 may include first to third layers D1, D2, and D3, the second dam part DMP2 may include first to fourth layers D1, D2, D3, and D4, and the third dam part DMP3 may include first and second layers D1 and D2.

One of the first dam part DMP1 and the second dam part DMP2 may set the boundary of the organic layer 142 in the peripheral region 100N when the organic layer 142 of the encapsulation layer 140 is formed. Accordingly, the organic layer 142 may be formed up to only one of the first dam part DMP1 and the second dam part DMP2.

The third dam part DMP3 may absorb external impact applied from the corner areas CN (refer to FIG. 1). Accordingly, the components of the display panel 100 may be effectively prevented from being damaged.

The first and second inorganic layers 141 and 143 of the encapsulation layer 140 may be in contact with each other in the peripheral region 100N and may cover the second pattern SD2.

According to an embodiment, a portion of the first electrode AE may extend to the peripheral region 100N and may be in contact with the second pattern SD2. A portion of the second electrode CE may extend from the peripheral region 100N and may be in contact with the portion of the first electrode AE that extends to the peripheral region 100N. Accordingly, the first pattern SD1, the second pattern SD2, the first electrode AE, and the second electrode CE may be connected together in the peripheral region 100N.

According to an embodiment, the first pattern SD1 and the second pattern SD2 may be lines that provide the second power voltage ELVSS to the light emitting element LD described with reference to FIG. 3B. The lines that provide the second power voltage ELVSS to the light emitting element LD (refer to FIG. 3B) may be provided in two layers and may reduce resistance.

FIG. 6B is an enlarged view illustrating a contact relationship between the end of the first pattern SD1 and the second pattern SD2 and an arrangement relationship between the first and second inorganic layers 141 and 143.

Referring to FIG. 6B, in an embodiment, the first pattern SD1 may include a first conductive layer CP1, a second conductive layer CP2, and a third conductive layer CP3 sequentially stacked on the second insulating layer 20. The first conductive layer CP1 and the third conductive layer CP3 may include a same material as each other, and the second conductive layer CP2 may have a greater thickness in the third direction DR3 than the first conductive layer CP1 and the third conductive layer CP3. According to an embodiment, the first conductive layer CP1 and the third conductive layer CP3 may include titanium, and the second conductive layer CP2 may include aluminum.

In an embodiment, an end C1-E of the first conductive layer CP1 may further protrude in a direction away from the display region 100A (refer to FIG. 6A) than an end C3-E of the third conductive layer CP3 does.

The end C1-E of the first conductive layer CP1 may further protrude in the direction away from the display region 100A (refer to FIG. 6A) than an end of a lower surface C2-B of the second conductive layer CP2 does, and the end C3-E of the third conductive layer CP3 may further protrude in the direction away from the display region 100A (refer to FIG. 6A) than an end of an upper surface C2-U of the second conductive layer CP2 does. Accordingly, the lower surface C2-B of the second conductive layer CP2 may be completely covered by the first conductive layer CP1, and the upper surface C2-U of the second conductive layer CP2 may be completely covered by the third conductive layer CP3. In an embodiment, as shown in FIG. 6B, a width CA of the inclined portion may be defined as a distance between the end of a lower surface C2-B of the second conductive layer CP2 and the end of an upper surface C2-U of the second conductive layer CP2 in the direction away from the display region 100A (refer to FIG. 6A).

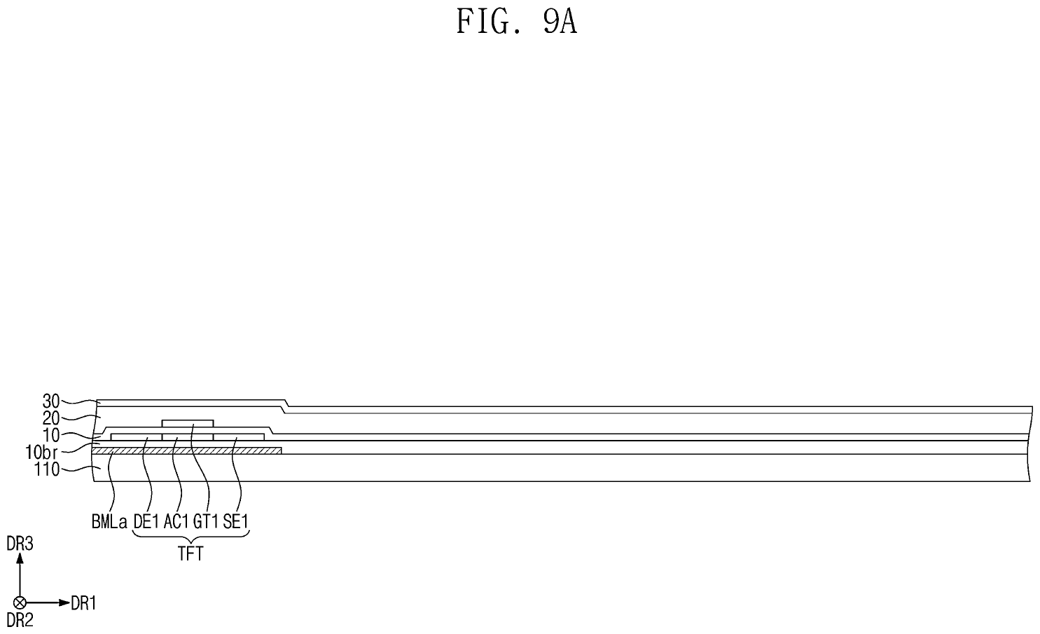

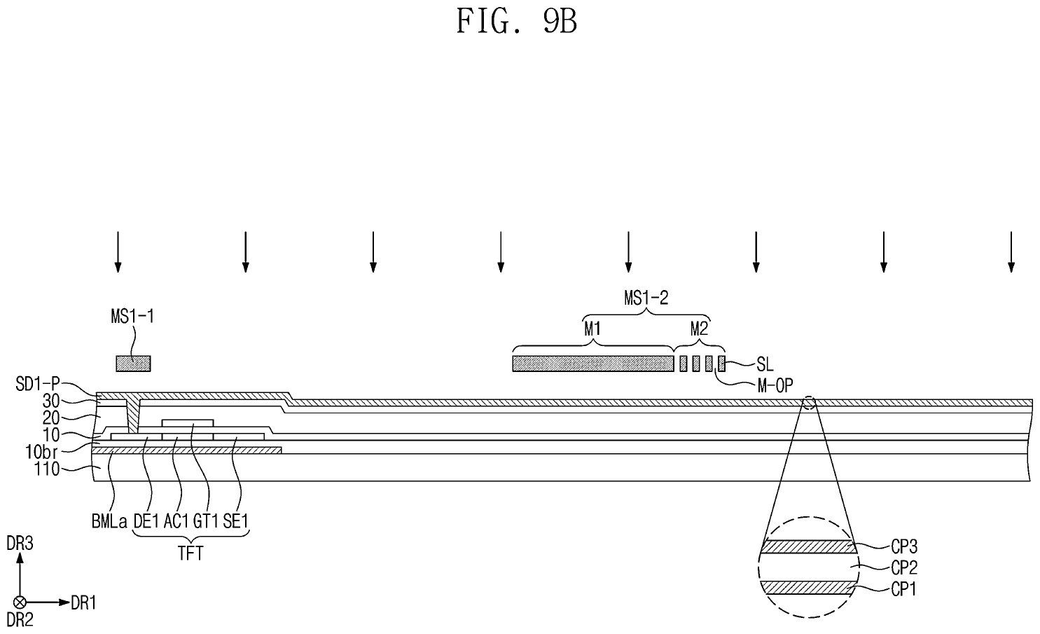

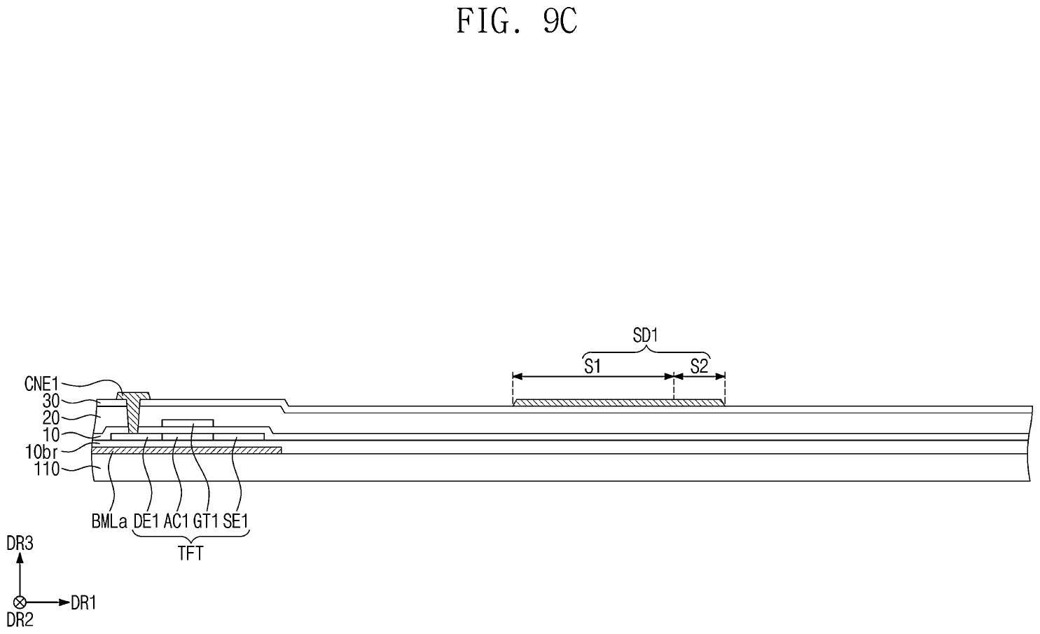

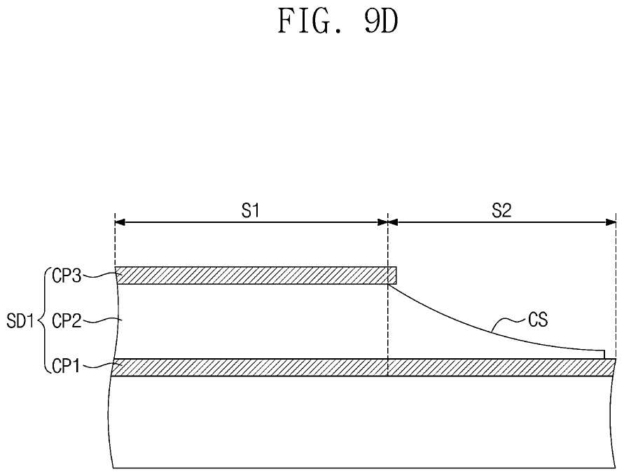

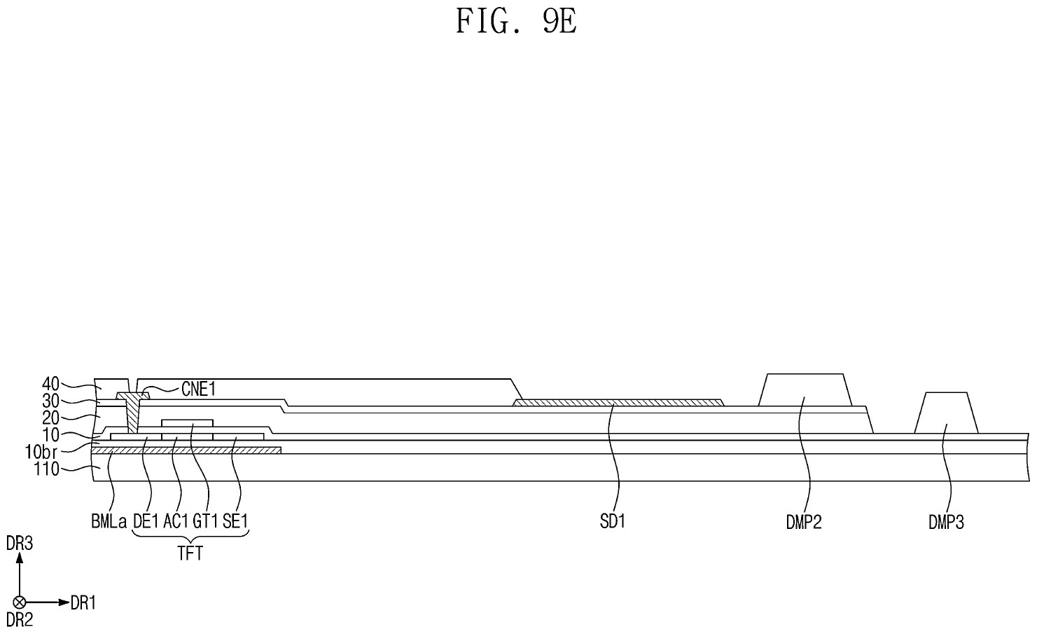

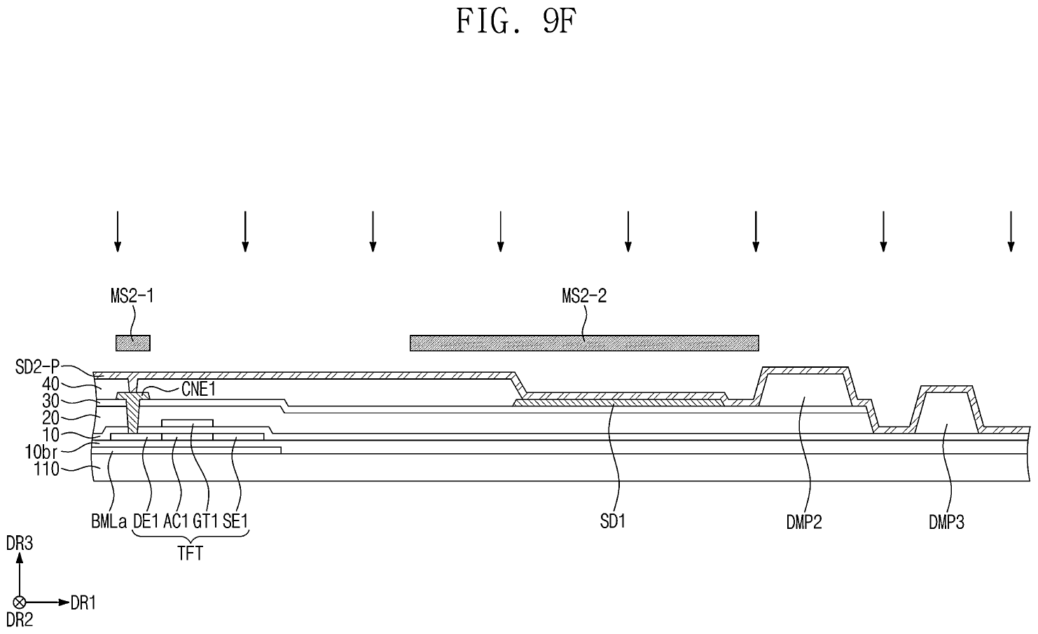

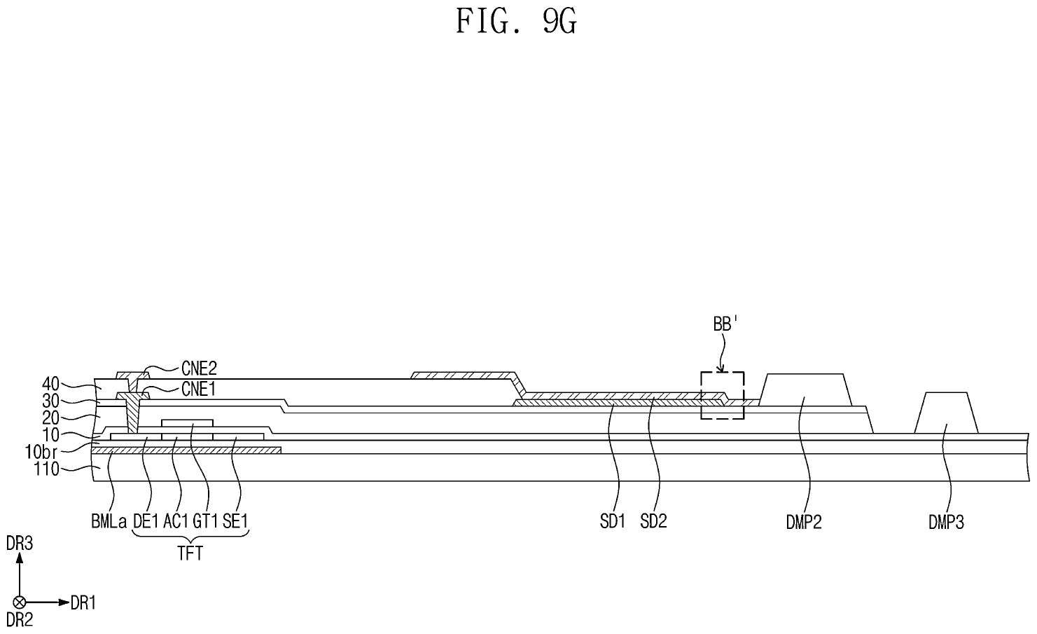

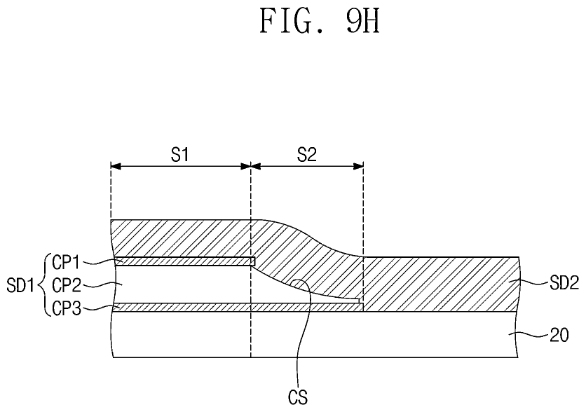

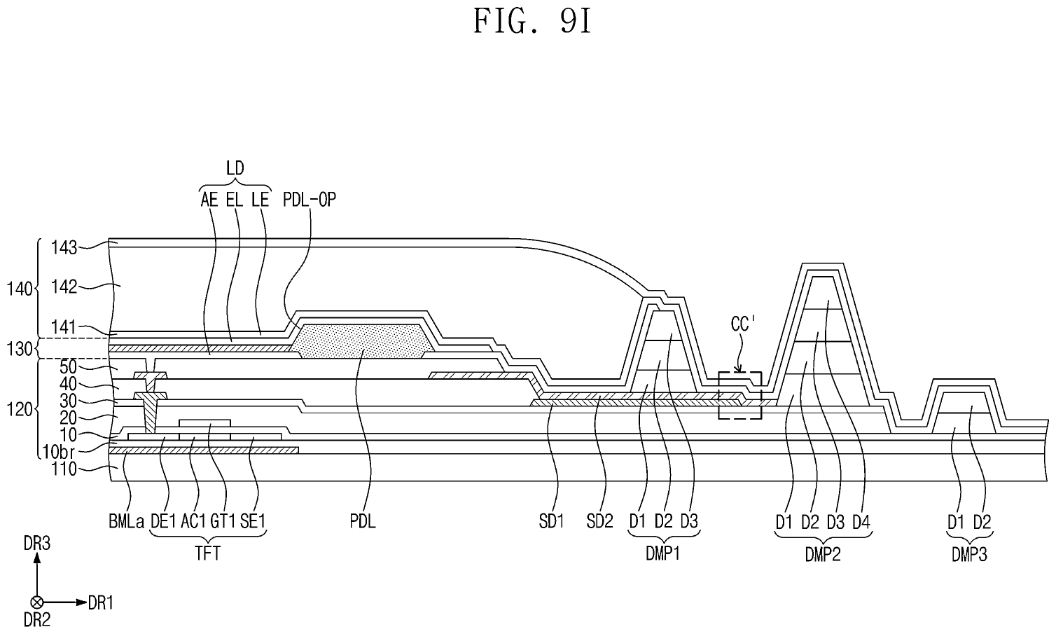

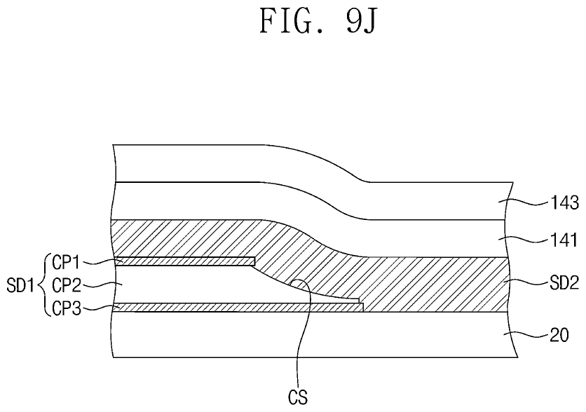

According to an embodiment, the end of the first pattern SD1 disposed away from the display region 100A (refer to FIG. 6A) may include an inclined portion CS. The inclined portion CS may be inclined at a predetermined angle. The inclined portion CS of the first pattern SD1 may be defined by the second conductive layer CP2. The inclined portion CS of the first pattern SD1 may be formed through a slit mask MS1-2 (refer to FIG. 9B) that will be described below. The inclined portion CS according to an embodiment may have a shape concave toward the base layer 110 (refer to FIG. 5).

In an embodiment, the inclined portion CS may have a width CA of about 6 micrometers (μm) to about 15 μm in the first direction DR1. The width CA of the inclined portion CS may be similar to the width of a portion of the slit mask MS1-2 (refer to FIG. 9B) that includes slits SL (refer to FIG. 9B).

According to an embodiment of the disclosure, the second pattern SD2, the first inorganic layer 141, and the second inorganic layer 143 may be gently formed at the end of the first pattern SD1 as the end of the first pattern SD1 includes the inclined portion CS having a predetermined slope. The first inorganic layer 141 and the second inorganic layer 143 may be in contact with each other in a region overlapping the inclined portion CS of the first pattern SD1.

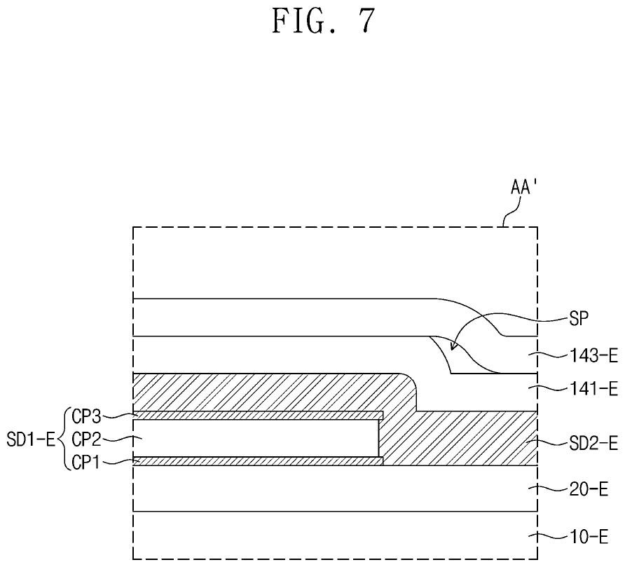

FIG. 7 illustrates a comparative example of the disclosure. In the comparative example, a first pattern SD1-E of FIG. 7 may be formed through a general mask rather than the slit mask MS1-2 (refer to FIG. 9B).

According to the comparative example, the first pattern SD1-E may not have an inclined portion at an end of the first pattern SD1-E. However, without being limited thereto, the end of the first pattern SD1-E may include an inclined portion inclined at a predetermined angle depending on etching properties of first to third conductive layers CP1, CP2, and CP3, and the inclined portion may have a width of less than about 5 μm.

A second pattern SD2-E is disposed on the first pattern SD1-E. In the comparative example, as shown in FIG. 7, a portion of the second pattern SD2-E that covers the end of the first pattern SD1-E may be vertically formed to correspond to the shape of the end of the first pattern SD1-E.

In this case, the step coverage of a first inorganic layer 141-E and a second inorganic layer 143-E that cover the second pattern SD2-E may be reduced, and therefore a lifted space SP may be formed between the first inorganic layer 141-E and the second inorganic layer 143-E in a region adjacent to the end of the first pattern SD1-E. If the lifted space SP is formed in one of the corner areas CN of the display device DD described with reference to FIG. 1, moisture and oxygen introduced into the corner areas CN may permeate into the display region 100A (refer to FIG. 6A) of the display panel 100 (refer to FIG. 5).

In an embodiment, as described above, the first pattern SD1 disposed in each of the corner areas CN of the display panel 100 (refer to FIG. 5) includes the inclined portion CS, such that the step coverage of the second pattern SD2, the first inorganic layer 141, and the second inorganic layer 143 disposed on the inclined portion CS may be improved. Accordingly, the first inorganic layer 141 and the second inorganic layer 143 may make contact with each other in the region overlapping the inclined portion CS of the first pattern SD1. Thus, moisture and oxygen introduced into the corner areas CN may be effectively prevented from permeating into the display region 100A (refer to FIG. 6A) of the display panel 100 (refer to FIG. 5). As a result, the display device DD having improved reliability and quality may be provided.

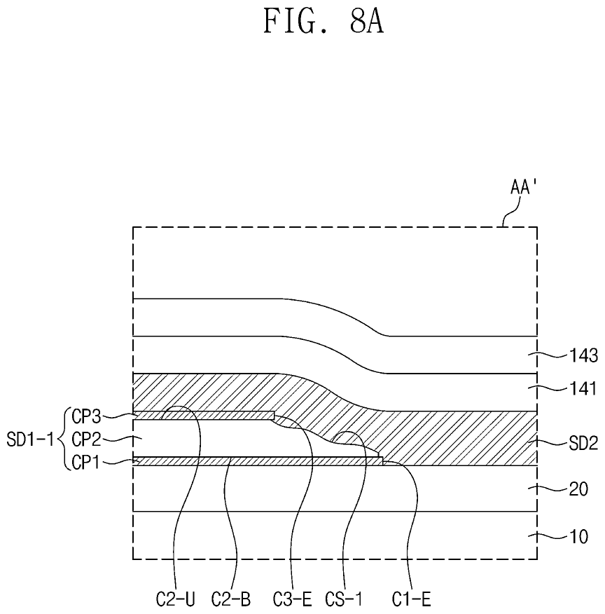

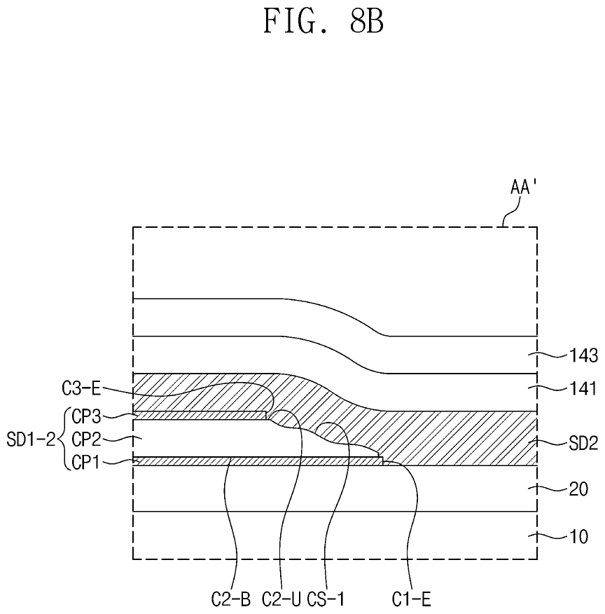

FIG. 8A is a cross-sectional view of a partial region of the display panel according to an embodiment of the disclosure. FIG. 8B is a cross-sectional view of a partial region of the display panel according to an embodiment of the disclosure. FIGS. 8A and 8B are enlarged views of region AA′ illustrated in FIG. 6A. In FIGS. 8A and 8B, components identical or similar to the components described with reference to FIGS. 1 to 6B will be assigned with identical or similar reference numerals, and any repetitive descriptions thereof will be omitted.

Referring to FIG. 8A, in an embodiment, a first pattern SD1-1 may be disposed on the second insulating layer 20. The first pattern SD1-1 may include a first conductive layer CP1, a second conductive layer CP2, and a third conductive layer CP3 sequentially stacked on the second insulating layer 20. The first conductive layer CP1 and the third conductive layer CP3 may include the same material, and the second conductive layer CP2 may have a greater thickness in the third direction DR3 than the first conductive layer CP1 and the third conductive layer CP3. According to an embodiment, the first conductive layer CP1 and the third conductive layer CP3 may include titanium, and the second conductive layer CP2 may include aluminum.

According to an embodiment, compared to an end C3-E of the third conductive layer CP3, an end C1-E of the first conductive layer CP1 may further protrude in the direction away from the display region 100A (refer to FIG. 6A).

The end C1-E of the first conductive layer CP1 may further protrude in the direction away from the display region 100A (refer to FIG. 6A) than an end of a lower surface C2-B of the second conductive layer CP2 does, and the end C3-E of the third conductive layer CP3 may further protrude in the direction away from the display region 100A (refer to FIG. 6A) than an end of an upper surface C2-U of the second conductive layer CP2 does. Accordingly, the lower surface C2-B of the second conductive layer CP2 may be completely covered by the first conductive layer CP1, and the upper surface C2-U of the second conductive layer CP2 may be completely covered by the third conductive layer CP3.

The end of the first pattern SD1-1 disposed away from the display region 100A (refer to FIG. 6A) may include an inclined portion CS-1. The inclined portion CS-1 may be inclined at a predetermined angle. The inclined portion CS-1 of the first pattern SD1-1 may be defined by the second conductive layer CP2. The inclined portion CS-1 of the first pattern SD1-1 may be formed through the slit mask MS1-2 (refer to FIG. 9B) that will be described below. In an embodiment, as shown in FIG. 8A, the inclined portion CS-1 may have an uneven surface on the cross-section.

A second pattern SD2 may cover the first pattern SD1-1. The first inorganic layer 141 may be disposed on the second pattern SD2, and the second inorganic layer 143 may be disposed on the first inorganic layer 141. The first inorganic layer 141 and the second inorganic layer 143 may make contact with each other in a region overlapping the inclined portion CS-1 of the first pattern SD1-1.

Hereinafter, an alternative embodiment shown in FIG. 8B will be described.

In such an embodiment, a first pattern SD1-2 may include a first conductive layer CP1, a second conductive layer CP2, and a third conductive layer CP3 sequentially stacked on the second insulating layer 20. In such an embodiment, an end C1-E of the first conductive layer CP1 may further protrude in the direction away from the display region 100A (refer to FIG. 6A) than an end C3-E of the third conductive layer CP3 does.

The end C1-E of the first conductive layer CP1 may further protrude in the direction away from the display region 100A (refer to FIG. 6A) than an end of a lower surface C2-B of the second conductive layer CP2.

According to an embodiment, the end C3-E of the third conductive layer CP3 may expose a portion of an upper surface C2-U of the second conductive layer CP2. A second pattern SD2 may make contact with the portion of the upper surface C2-U of the second conductive layer CP2 that is exposed from the third conductive layer CP3.

FIGS. 9A to 9J are cross-sectional views illustrating a display panel manufacturing method according to an embodiment of the disclosure. Components identical or similar to the components described with reference to FIGS. 1 to 6B will be assigned with identical or similar reference numerals, and any repetitive detailed descriptions thereof will be omitted. FIG. 9H is an enlarged view of region BB′ of FIG. 9G, and FIG. 9H is an enlarged view of region CC′ of FIG. 9I.

Referring to FIG. 9A, an embodiment of the display panel manufacturing method according to the disclosure may include a process of providing a preliminary display panel.

The preliminary display panel may include the base layer 110, the buffer layer 10br, the first insulating layer 10, the second insulating layer 20, and the third insulating layer 30.

The active region AC1, the drain region DE1, the source region SE1, and the gate GT1 of the transistor TFT may be formed in the preliminary display panel. The preliminary display panel may further include the rear metal layer BMLa that overlaps the active region AC1, the drain region DE1, and the source region SE1.

The rear metal layer BMLa may be formed on the base layer 110. The active region AC1, the drain region DE1, and the source region SE1 may be formed on the buffer layer 10br, and the gate GT1 may be formed on the first insulating layer 10.

Referring to FIG. 9B, an embodiment of the display panel manufacturing method according to the disclosure may include a process of forming a contact hole, a process of applying a first conductive material SD1-P, and a process of etching the first conductive material SD1-P through a first mask MS1-1 and MS1-2.

The contact hole may be formed through the first to third insulating layers 10, 20, and 30 overlapping the drain region DE1 and may expose a portion of the drain region DE1.

The first conductive layer SD1-P may be formed on the third insulating layer 30. The first conductive material SD1-P may fill the contact hole through which the portion of the drain region DE1 is exposed. The first conductive layer SD1-P may include the first to third conductive layers CP1, CP2, and CP3 stacked in three layers.

The first conductive layer CP1 and the third conductive layer CP3 may include a same material as each other, and the second conductive layer CP2 may have a greater thickness in the third direction DR3 than the first conductive layer CP1 and the third conductive layer CP3. According to an embodiment, the first conductive layer CP1 and the third conductive layer CP3 may include titanium, and the second conductive layer CP2 may include aluminum.

The first mask MS1-1 and MS1-2 may include a normal mask MS1-1 and the slit mask MS1-2. The normal mask MS1-1 may be a mask for forming the first connecting electrode CNE1 described with reference to FIG. 6A, and the slit mask MS1-2 may be a mask for forming the first pattern SD1 described with reference to FIG. 6A.

The slit mask MS1-2 may include a first portion M1 and a second portion M2. The second portion M2 may include the plurality of slits SL. The slits SL may be spaced apart from each other, and slit openings M-OP may be defined in the adjacent slits SL. As light passes through the slit openings M-OP in an exposure process and a developing process, the inclined portion CS of the second conductive layer CP2 described with reference to FIG. 6A may be formed.

According to an embodiment, the second portion M2 may have a width in a range of about 6 μm to about 15 μm. Accordingly, the width of the inclined portion CS of the second conductive layer CP2 described with reference to FIG. 6A may be in a range of about 6 μm to about 15 μm. The number of slits SL may be greater than or equal to 3 and less than or equal to 10. The pitch between the adjacent slits SL may be in a range of about 1.5 μm to about 3 μm.

Referring to FIGS. 9C and 9D, after the process of etching the first conductive material SD1-P through the first mask MS1-1 and MS1-2, the first connecting electrode CNE1 connected to the drain region DE1 may be formed in the portion overlapping the normal mask MS1-1, and the first pattern SD1 may be formed on the portion overlapping the slit mask MS1-2. The first pattern SD1 may include a first pattern portion S1 overlapping the portion of the slit mask MS1-2 other than the slits SL and a second pattern portion S2 overlapping the slits SL.

Referring to FIG. 9D, the first conductive layer CP1 disposed in the second pattern portion S2 may be longer than the third conductive layer CP3 disposed in the second pattern portion S2. According to an embodiment, the second conductive layer CP2 disposed in the second pattern portion S2 may include the inclined portion CS. The inclined CS may have a shape concave toward the base layer 110.

Referring to FIG. 9E, the display panel manufacturing method according to the disclosure may include a process of forming the fourth insulating layer 40 and a process of making the fourth insulating layer 40 subject to patterning.

The fourth insulating layer 40 may be formed on the third insulating layer 30. The fourth insulating layer 40 may include an organic material.

In the process of making the fourth insulating layer 40 subject to patterning, a contact hole for exposing a portion of the first connecting electrode CNE1 may be formed through the fourth insulating layer 40, and at least a portion of the first pattern SD1 may be exposed. In addition, the lowermost layers of the second dam part DMP2 and the third dam part DMP3 described with reference to FIG. 6A may be formed.

In the process of making the fourth insulating layer 40 subject to patterning, a portion of the third insulating layer 30 and a portion of the second insulating layer 20 may be removed, and the third dam part DMP3 may be formed on the first insulating layer 10.

Referring to FIGS. 9F, 9G, and 9H, an embodiment of the display panel manufacturing method according to the disclosure may include a process of applying a second conductive material SD2-P and a process of etching the second conductive material SD2-P through a second mask MS2-1 and MS2-2.

The second conductive material SD2-P may be formed on the fourth insulating layer 40. The second conductive material SD2-P may fill the contact hole for exposing the portion of the first connecting electrode CNE1. The second conductive material SD2-P may be provided in a single layer.

The second mask MS2-1 may include a mask 2-1 MS2-1 and a mask 2-2 MS2-2. The mask 2-1 MS2-1 may be a mask for forming the second connecting electrode CNE2 described with reference to FIG. 6A, and the mask 2-2 MS2-2 may be a mask for forming the second pattern SD2 described with reference to FIG. 6A.

Referring to FIGS. 9G and 9H, after the process of etching the second conductive material SD2-P through the second mask MS2-1 and MS2-2, the second connecting electrode CNE2 connected to the first connecting electrode CNE1 may be formed in the portion overlapping the mask 2-1 MS2-1, and the second pattern SD2 may be formed on the portion overlapping the mask 2-2 MS2-2. The second pattern SD2 may cover at least a portion of the first pattern portion S1 of the first pattern SD1 and may cover the second pattern portion S2 of the first pattern SD1. The second pattern SD2 may cover an end of the second pattern portion S2.

In an embodiment, as illustrated in FIG. 9H, the second pattern SD2 may be gently formed at the end of the first pattern SD1 along the inclined portion CS to correspond to the shape of the inclined portion CS of the second conductive layer CP2 of the first pattern SD1.

Referring to FIGS. 91 and 9J, an embodiment of the display panel manufacturing method according to the disclosure may include a process of forming the light emitting element LD, a process of forming the encapsulation layer 140, and a process of forming the dam parts DMP1, DMP2, and DMP3.

The process of forming the light emitting element LD may include a process of forming, on the fourth insulating layer 40, the fifth insulating layer 50 provided with a contact hole defined therein and forming the first electrode AE on the fifth insulating layer 50, a process of forming the pixel defining layer PDL, a process of forming the light emitting structure EL, and a process of forming the second electrode CE.

The encapsulation layer 140 may include or be formed of the first inorganic layer 141, the organic layer 142, and the second inorganic layer 143 that are sequentially stacked one above another. The boundary of the organic layer 142 may be determined by one of the first and second dam parts DMP1 and DMP2. The layers included in the first to third dam parts DMP1, DMP2, and DMP3 may be formed in a process of applying organic layers to the front surface of the base layer 110 and making the organic layers subject to patterning.

In an embodiment of the display panel manufacturing method according to the disclosure, the end of the first pattern SD1 may be formed between the first dam part DMP1 and the second dam part DMP2.

In an embodiment, as illustrated in FIG. 9J, the first inorganic layer 141 and the second inorganic layer 143 may make contact with each other in the region overlapping the inclined portion CS of the first pattern SD1 and thus may effectively block an inflow path of moisture and oxygen permeating into the corner areas CN of the peripheral region 100N described with reference to FIG. 1.

According to embodiments of the disclosure, moisture and oxygen introduced into the corner areas of the display panel may be effectively prevented from permeating into the display region of the display panel. Accordingly, the display panel having improved reliability and quality may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a base layer on which a display region and a peripheral region are defined;
a transistor disposed on the base layer, wherein the transistor includes a semiconductor pattern overlapping the display region and a control electrode overlapping the semiconductor pattern;
a first connecting electrode disposed on the semiconductor pattern and connected to the semiconductor pattern;
a second connecting electrode disposed on the first connecting electrode and connected to the first connecting electrode;
a light emitting element including a first electrode overlapping the display region and connected to the second connecting electrode, a second electrode disposed over the first electrode, and an emission pattern disposed between the first electrode and the second electrode;
an encapsulation layer covering the light emitting element;
a first pattern disposed in a same layer as the first connecting electrode; and
a second pattern disposed in a same layer as the second connecting electrode, wherein the second pattern overlaps the peripheral region and covers an end of the first pattern disposed away from the display region,
wherein the end of the first pattern includes an inclined portion inclined at a predetermined angle.

2. The display panel of claim 1, wherein in the peripheral region, the second electrode contacts with the first electrode, and
wherein in the peripheral region, the first electrode contacts with the second pattern.

3. The display panel of claim 2, wherein the light emitting element receives a power voltage through the first pattern and the second pattern.

4. The display panel of claim 1, wherein the first connecting electrode and the first pattern include a same material as each other, and
wherein the second connecting electrode and the second pattern include a same material as each other.

5. The display panel of claim 1, wherein the first pattern includes a first conductive layer, a second conductive layer, and a third conductive layer sequentially stacked one on another,
wherein the first conductive layer and the third conductive layer include a same material as each other, and
wherein the inclined portion is defined by the second conductive layer.

6. The display panel of claim 5, wherein an end of the first conductive layer is farther away from the display region than an end of the third conductive layer is.

7. The display panel of claim 5, wherein an end of the first conductive layer further protrudes in a direction away from the display region than an end of a lower surface of the second conductive layer does, and
wherein an end of the third conductive layer further protrudes in the direction away from the display region than an end of an upper surface of the second conductive layer does.

8. The display panel of claim 5, wherein an end of the first conductive layer further protrudes in a direction away from the display region than an end of a lower surface of the second conductive layer does,
wherein an end of an upper surface of the second conductive layer further protrudes in the direction away from the display region than an end of the third conductive layer does, and
wherein a portion of the upper surface of the second conductive layer is exposed from the third conductive layer.

9. The display panel of claim 5, wherein on a cross-section, the inclined portion is concave toward the base layer.

10. The display panel of claim 5, wherein on a cross-section, the inclined portion has an uneven surface.

11. The display panel of claim 5, wherein the first conductive layer and the third conductive layer include titanium,
wherein the second conductive layer includes aluminum, and
wherein the second conductive layer has a thickness greater than a thickness of the first conductive layer and a thickness of the third conductive layer.

12. The display panel of claim 1, wherein the encapsulation layer includes a first inorganic layer covering the light emitting element, a second inorganic layer disposed over the first inorganic layer, and an organic layer disposed between the first inorganic layer and the second inorganic layer, and
wherein the first inorganic layer and the second inorganic layer contact with each other in the peripheral region and cover the second pattern.

13. The display panel of claim 12, wherein the first inorganic layer and the second inorganic layer contact with each other in a region overlapping the inclined portion.

14. The display panel of claim 12, further comprising:
a buffer layer disposed on the base layer, wherein the buffer layer is disposed between the base layer and the semiconductor pattern;
a first insulating layer disposed on the buffer layer, wherein the first insulating layer is disposed between the buffer layer and the control electrode;
a second insulating layer disposed on the first insulating layer;
a third insulating layer disposed on the second insulating layer, wherein the third insulating layer is disposed between the second insulating layer and the first connecting electrode;
a fourth insulating layer disposed on the third insulating layer, wherein the fourth insulating layer is disposed between the third insulating layer and the second connecting electrode;
a fifth insulating layer disposed on the fourth insulating layer, wherein the fifth insulating layer is disposed between the fourth insulating layer and the first electrode;
a pixel defining layer disposed on the fifth insulating layer, wherein the pixel defining layer is provided with an opening defined therein to expose at least a portion of the first electrode;
a first dam part overlapping the peripheral region, wherein the first dam part includes a same material as at least one selected from the first to fifth insulating layers; and
a second dam part disposed farther away from the display region than the first dam part is, wherein the second dam part includes a same material as at least one selected from the first to fifth insulating layers.

15. The display panel of claim 14, wherein the end of the first pattern is disposed between the first dam part and the second dam part.

16. The display panel of claim 14, wherein a boundary of the organic layer is defined by one of the first dam part and the second dam part.

17. The display panel of claim 14, further comprising:
a third dam part disposed on the first insulating layer overlapping the peripheral region, wherein the third dam part is disposed farther away from the display region than the second dam part is, and the third dam part includes a same material as at least one selected from the first to fifth insulating layers.

18. The display panel of claim 14, wherein the first connecting electrode is connected to the semiconductor pattern through a first contact hole defined in the first insulating layer, the second insulating layer, and the third insulating layer,
wherein the second connecting electrode is connected to the first connecting electrode through a second contact hole defined in the fourth insulating layer, and
wherein the first electrode is connected to the second connecting electrode through a third contact hole defined in the fifth insulating layer.

19. The display panel of claim 1, wherein the display region includes long sides and short sides which cross each other,
wherein points where the long sides and the short sides meet are defined as corners, and
wherein the first pattern and the second pattern contact with each other in corner areas of the peripheral region adjacent to the corners.

20. The display panel of claim 1, wherein the inclined portion has a width in a range of about 6 μm to about 15 μm.
